(19) United States
(12) Patent Application Publication
(10) Pub. No.: US 2008/0068798 A1
(43) Pub. Date: Mar. 20, 2008

(54) OUTSIDE PLANT CABINET THERMAL SYSTEM

(76) Inventors: Mark Hendrix, Richardson, TX (US); David BARTEK, Plano, TX (US); Chuck Mann, Omaha, NE (US); Joseph Yeh, Plano, TX (US)

Correspondence Address: MG-IP Law, PLLC, P.O. BOX 1364, FAIRFAX, VA, 22038-1364, US

(21) Appl. No.: 11/858,711

(22) Filed: Sep. 20, 2007

Related U.S. Application Data
(60) Provisional application No. 60/845,762, filed on Sep. 20, 2006.

(51) Int. Cl. H05K 7/20; H05K 5/02

(52) U.S. Cl. 361/696; 361/692

(57) ABSTRACT

An outdoor equipment cabinet includes a housing with a first door for accessing an equipment compartment within the housing. A battery compartment is located proximate a bottom of the housing. First and second air vents are located in an upper half of the cabinet. At least one fan moves air from the first vent, down to the battery compartment and then up and out of the second vent. In some embodiments, the first door includes the second vent, and a dual wall construction leading to a heat exchanger mounted to the first door. Air passes through the dual wall construction of the first door and through the heat exchanger to regulate an air temperature within the equipment compartment, and then passes out the second vent. The first vent may be provided in a second door which also includes a dual wall construction to guide incoming air to the battery compartment.

This application claims the benefit of U.S. Provisional Application No. 60/845,762, filed Sep. 20, 2006, the entire contents of which are herein incorporated by reference.

### BACKGROUND OF THE INVENTION

1. Field of the Invention

The present invention relates to a cabinet. More particularly, the present invention relates to an outdoor cabinet for housing communications equipment, which includes a thermal regulating system to maintain an internal temperature of the cabinet within prescribed limits.

2. Description of the Related Art

There are many types of optical and electronic equipment that must be located in an outdoor environment. For example, telecommunication equipment, networking equipment, and cable television equipment (generally referred to as “communication equipment”) are often housed in an enclosure or cabinet located outdoors. In the communications industry, such equipment is often referred to as “outside plant equipment”. Outside plant equipment can include such items as amplifiers, splitters, digital subscriber line access multiplexers (DSLAMs), surge protectors, etc.

It is essential that such equipment be operated within a prescribed temperature range and be protected from outside environment contaminates (e.g., water, dust, dirt, sand, insects, rodents). To this end, outdoor cabinets have been developed to house such communication equipment in a highly weather-tight and sealed manner.

Such equipment is known to generate a great deal of heat, especially when a piece of equipment includes a laser, as is the case with many fiber optic devices. This heat must be dissipated to ensure proper operation of the equipment and to prolong the life of the equipment. If the equipment is tightly sealed, a heat dissipating system needs to be employed.

Further, in many environments the cabinets, housing such equipment, are subjected to radiant heat from direct sunlight and light reflected from ground surfaces or adjacent buildings. Radiant heat sources can also greatly increase the interior temperature of the cabinet, which further exacerbates heat problems related to equipment operation.

There are air conditioning systems available in the prior art that may be used in conjunction with outside plant equipment cabinets to aid in maintaining a constant temperature environment for the internal communications equipment. However, an air conditioning system may not be cost effective for all applications. The initial cost of an air conditioning system is high. Further, an air conditioning system consumes a lot of power, produces noise and requires period maintenance and charging.

An alternative approach has been suggested in several prior U.S. Patents, wherein a heat exchanger is employed to exchange heat between the “internal air” of the cabinet and the “external air” of the environment. The heat exchanger maintains a physical separation between the internal and external air flows so as to prevent contamination of the equipment within the cabinet. U.S. Pat. Nos. 5,570,740; 5,603,376; 5,832,988; 6,119,768, 6,164,369; 6,317,320, 6,494,252; 6,749,498, all of which are herein incorporated by reference, disclose outdoor equipment cabinets with heat exchangers for cooling internal communication equipment.

### SUMMARY OF THE INVENTION

The Applicants have appreciated one or more drawbacks associated with the designs of the prior art.

With the cabinets of the prior art, outside air, which is drawn into the cabinet for use by the heat exchanger, is taken from a location close to the ground level. Contaminants (e.g., pollen, dust, weeds, grass clippings, seeds, crawling insects) are primarily located at or near the ground level of the cabinet. Therefore, contaminants may be pulled into the cabinet and heat exchanger. Although these contaminants do not enter the equipment chamber of the cabinet due to the separation between the outside air flow and the interior air flow within the heat exchanger, these contaminants can decrease the performance ability of the heat exchanger and lead to periodic maintenance requirements to clear the accumulated contaminants from the outside air path within the cabinet.

The Applicants have also appreciated that the radiant heating of the cabinet could be greatly improved by a system to cool one or more of the outer walls of the cabinet. The Applicants have also appreciated a need in the art for a cabinet which improves on one or more of the following attributes: (A) minimization of acoustic noise from active components within the cabinet (such as fans); (B) a more Compact overall size and increased density of electronic equipment within the housing; (C) a more streamlined outer housing shell; (D) a better directing of air flow to optimize the cooling effects within the cabinet; and (E) a fan redundancy to ensure performance in the case of a fan failure.

The Applicants have also appreciated a need for a cabinet which is simple in design, rugged, more flexible as to end uses, easy to manufacture and/or less expensive to manufacture.

It is an object of the present invention to address one or more of the drawbacks of the prior art outdoor equipment cabinets and/or Applicants' appreciated needs in the art.

These and other objects are accomplished by an outdoor equipment cabinet including a housing with a first door for accessing an equipment compartment within the housing. A battery compartment is located proximate a bottom of the housing. First and second air vents are located in an upper half of the cabinet. At least one fan moves air from the first vent, down to the battery compartment and then up and out of the second vent. Preferably, the first door includes the second vent, and a dual wall construction leading to a heat exchanger mounted to the first door. Air passes through the dual wall construction of the first door and through the heat exchanger to regulate an air temperature within the equipment compartment, and then proceeds out the second vent. The first vent may be provided in a second door which also includes a dual wall construction to guide incoming air to the battery compartment.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limits of the present invention, and wherein:

FIG. 1 is a perspective view of an outdoor equipment cabinet in a closed state, in accordance with the present invention;

FIG. 2 is a perspective view of the outdoor equipment cabinet of FIG. 1 with a splice chamber door and an equipment compartment door open;

FIG. 3 is a perspective view of the outdoor equipment cabinet of FIG. 2 with a top panel removed;

FIG. 4 is a cross sectional view taken along line IV-IV of FIG. 3, which illustrates an outside air flow passage within the splice chamber door;

FIG. 5 is a cross sectional view taken along line V-V of FIG. 3, which illustrates the outside air flow passage within the equipment compartment door;

FIG. 6 is a cross sectional view taken along line VI-VI of FIG. 3, which illustrates an interior air flow passage within the equipment compartment door;

FIG. 7 is a cross sectional view taken along line VII-VII of FIG. 1, which illustrates the outside air flow inside of the cabinet; and

FIG. 8 is a cross sectional view taken along line VIII-VIII of FIG. 1, which illustrates the interior air flow inside of the cabinet.

### DETAILED DESCRIPTION OF THE INVENTION

The present invention now is described more fully hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

Like numbers refer to like elements throughout. In the figures, the thickness of certain lines, layers, components, elements or features may be exaggerated for clarity. Broken lines illustrate optional features or operations unless specified otherwise.

The terminology used herein is for the purpose of describing particular embodiments only and is not intended to be limiting of the invention. Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein. Well-known functions or constructions may not be described in detail for brevity and/or clarity.

As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. As used herein, phrases such as “between X and Y” and “between about X and Y” should be interpreted to include X and Y. As used herein, phrases such as “between about X and Y” mean “between about X and about Y.” As used herein, phrases such as “from about X to Y” mean “from about X to about Y.”

It will be understood that when an element is referred to as being “on”, “attached” to, “connected” to, “coupled” with, “contacting”, etc., another element, it can be directly on, attached to, connected to, coupled with or contacting the other element or intervening elements may also be present. In contrast, when an element is referred to as being, for example, “directly on”, “directly attached” to, “directly connected” to, “directly coupled” with or “directly contacting” another element, there are no intervening elements present. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper”, “lateral”, “left”, “right” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is inverted, elements described as “under” or “beneath” other elements or features would then be oriented “over” the other elements or features. The device may be otherwise oriented (rotated 90 degrees or at other orientations) and the descriptors of relative spatial relationships used herein interpreted accordingly.

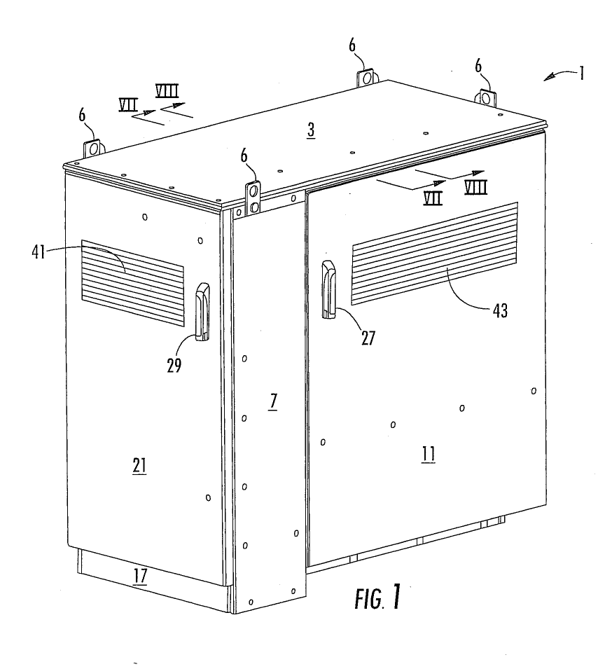

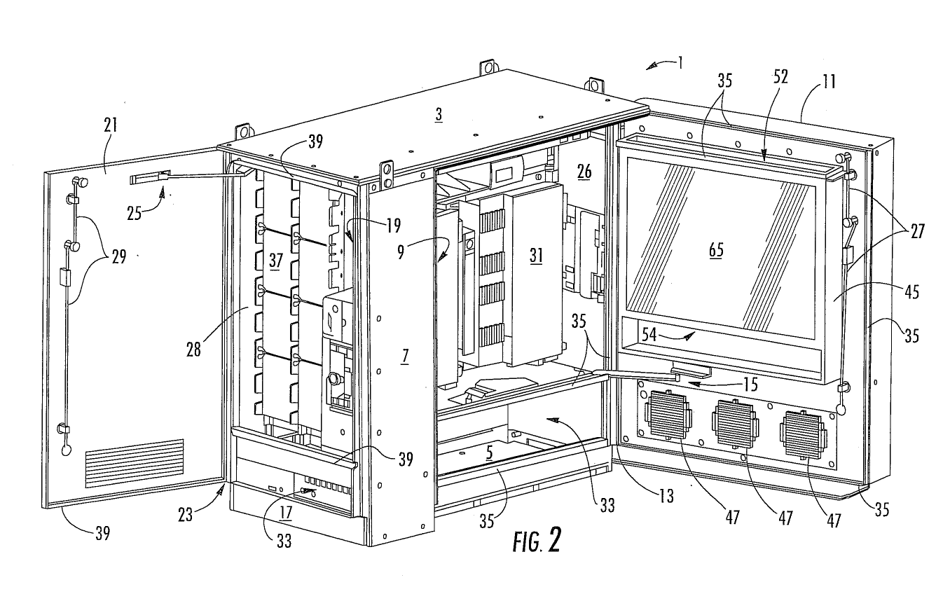

FIGS. 1 and 2 are perspective views of an outdoor equipment cabinet 1 in a closed state and an open state, respectively. The cabinet 1 includes a housing formed by a plurality of sidewalls, a top panel 3 and a bottom floor 5. Lifting tabs 6 may optionally be provided around a periphery of the top panel 3, so that the cabinet 1 may be hoisted to a desired location using lifting cables.

A first sidewall 7 includes a first opening 9. A first door 11 is attached to the housing and has a first position providing access to the first opening 9 and a second position closing access to the first opening 9. The first door 11 may be attached to the housing by a first hinge 13. A first keeper 15, to latch the first door 11 in the first (open) position, may reside between the housing and the first door 11.

A second sidewall 17 includes a second opening 19. A second door 21 is attached to the housing and has a first position providing access to the second opening 19 and a second position closing access to the second opening 19. The second door 21 may be attached to the housing by a second hinge 23. A second keeper 25, to latch the second door 21 in the first (open) position, may reside between the housing and the second door 21.

The first door 11 may include a first latch assembly 27 to hold the first door 11 in the second (closed) position. The first latch assembly 27 may be key-operated to prevent unauthorized access to the interior of the cabinet 1. Likewise, the second door 21 may include a second latch assembly 29 to hold the second door 21 in the second (closed) position. The second latch assembly 29 may also be key-operated to prevent unauthorized access to the interior of the cabinet 1. A third sidewall 26 and a fourth sidewall 28 of the housing may be formed as fixed or removable panels. Alternatively, the third and fourth sidewalls 26 and 28 may have third and fourth doors (not illustrated) to provide access to other portions within the cabinet 1.

An equipment compartment 31 resides within the housing. The equipment compartment 31 is accessible via the first opening 9. The equipment compartment 31 houses pieces of optical and/or electronic equipment 32, which may be sensitive and therefore, should be protected against contamination by water, dust, insects, etc., and which may require maintaining within a prescribed temperature range. Such equipment 32 may include amplifiers, splitters, digital subscriber line access multiplexers (DSLAMs), surge protectors, etc.

A battery compartment 33 is located proximate the bottom floor 5 of the housing and beneath the electronics compartment 31. Batteries (not shown) would be placed upon the bottom floor 5. Alternatively, a roller tray (not shown) could be supported on the bottom floor 5 or by slide rails attached to the sidewalls of the housing, and the batteries could reside on the rolling tray so as to be easily removed from the housing for maintenance and/or replacement. Typically, a 220 volt power line is connected to the housing 1 to power the optical/electronic equipment 32 and to keep the batteries charged to power the optical/electronic equipment 32 in the event of a power interruption.

The first door 11 closes access to the equipment compartment 31 and the battery compartment 33 when in its second position. One or more first gaskets or seals 35 may be attached to the rims of the compartments 31 and 33 and/or the interior side of the first door 11 to seal to the first door 11 to the compartments 31 and 33 in a substantially air-tight manner.

A connection or splice chamber 37 also resides within the housing. The splice chamber 37 is accessible via the second opening 19. The splice chamber 37 houses connections between service provider lines and customer lines and organization/labeling devices to hold the splices in an orderly fashion. Such splices may include fiber to fiber splices. Also, such splices may include copper-to-copper splices. The splice chamber 37 may also include patch panels or similar interconnection devices, whereby a service technician may make communication connections to best serve the requirements of the customers' final system. Devices within the splice chamber 37 may need to be kept relatively free of contaminants, but are typically more immune to temperature variations, as compared to the requirements of the equipment within the equipment chamber 31.

The second door 21 closes access to the splice chamber 37 and the battery chamber 33 when in its second position. One or more second gaskets or seals 39 may be attached to the rims of the splice chamber 37 and the battery compartment 33 and/or the interior side of the second door 21 to seal to the second door 21 to the splice chamber 37 and battery compartment 33 in a substantially air-tight manner.

Now, a temperature regulating system, in accordance with one embodiment of the present invention, will be described. A first air vent 41 is located in an upper half of the cabinet 1 relative to a ground level supporting the cabinet 1. A second air vent 43 is also located in an upper half of the cabinet 1 relative to a ground level supporting the cabinet 1. As best seen in FIG. 1, preferably the first air vent 41 is located proximate a top of the second door 21, and the second air vent 43 is located proximate a top of the first door 11.

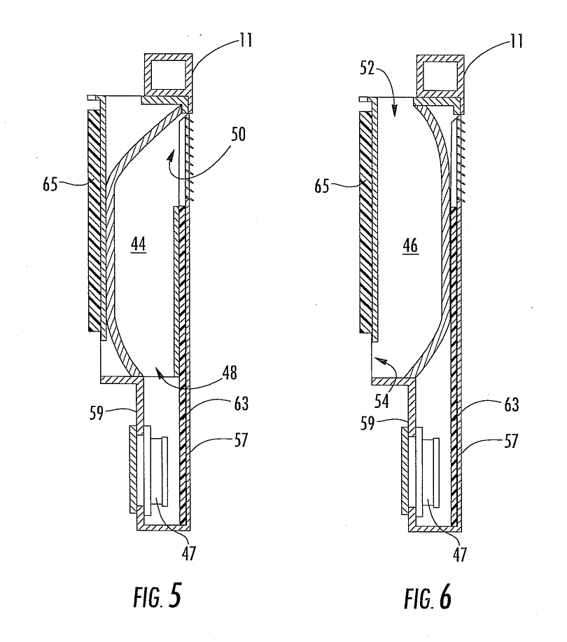

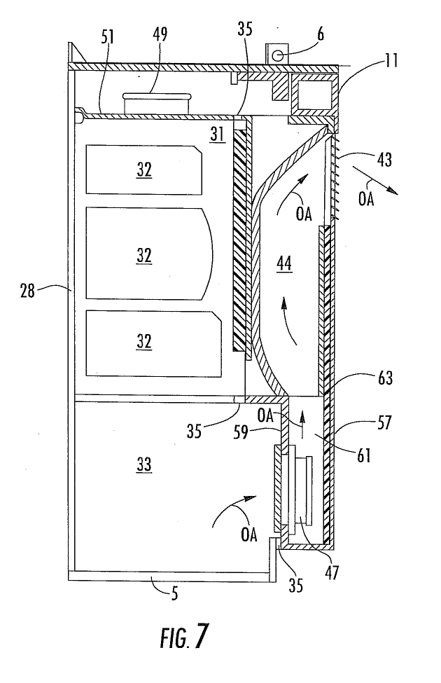

A heat exchanger 45 is directly attached to the first door 11. The heat exchanger 45 has first and second air flow passages 44 and 46 formed therein (FIGS. 5 and 6) which are thermally conductive with each other so as to permit a heat exchange therebetween. However, the first and second air flow passages 44 and 46 are formed within the heat exchanger 45 so as to prevent leakage of air between the first air flow passages 44 and the second air flow passages 46.

In one embodiment, the heat exchanger 45 includes a plurality of fins, which form the first and second air flow passages 44 and 46 therebetween. The first air flow passages 44 include a plurality of first spaces between the fins of the heat exchanger 45, and the second air flow passages 46 include a plurality of second spaces between the fins of the heat exchanger 45. In a preferred embodiment, the first and second air flow passages 44 and 45 alternate between the fins within the heat exchanger 45 in a pattern, such as one-to-one or two-to-two. for example, the heat exchanger 45 may include a plurality of spaced heat-transferring fins (e.g. one hundred), with the odd numbered spaces between heat fins (e.g. fifty spaces) constituting the first air flow passages 44 and the even numbered spaces between heat fins (e.g. 49 spaces) constituting the second air flow passages 46.

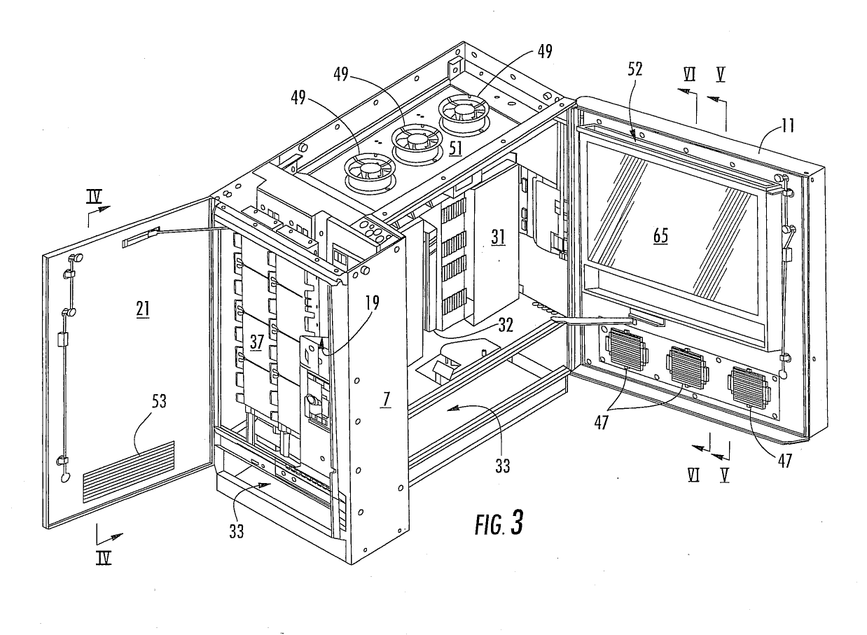

FIGS. 5 and 6 are cross sectional views taken along lines V-V and VI-VI in FIG. 3, respectively. FIG. 5 is taken along a cross section of the first door 11 to illustrate one of the odd numbered spaces constituting one of the first air flow passages 44. FIG. 6 is taken along a cross section of the first door 11 to illustrate one of the even numbered spaces constituting one of the second air flow passages 46.

As can be seen in FIGS. 5 and 6, the first air flow passages 44 connect a first air input 48 of the heat exchanger 45 to a first air output 50 of the heat exchanger 45. The second air flow passages 46 connect a second air input 52 of the heat exchanger 45 to a second air output 54 of the heat exchanger 45.

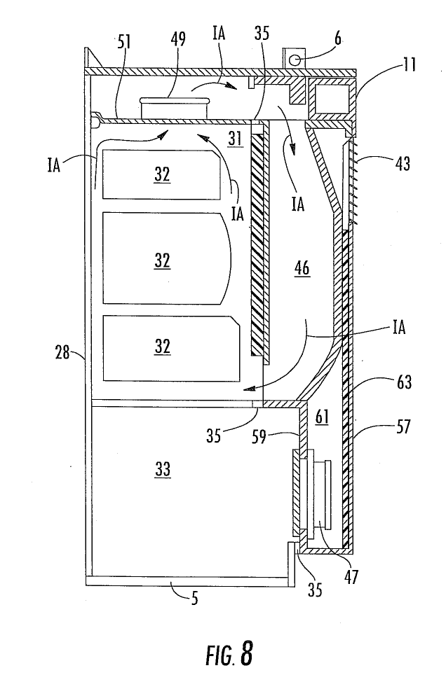

The heat exchanger 45 allows a thermal transfer of heat between the first and second air flow passages 44, 46, while preventing any mixing of the first and second air flows. The general design of such a heat exchanger 45 may employ bent fins and is known in the art, and sold by such companies as Pentair of St. Paul, Minn. and/or Seifert mtm Systems, Inc. of North Kingstown, R.I. However, the modified location and relative placements of the inputs and outputs of the heat exchanger 45 to cooperate with the air paths within a dual wall structure of a door, as illustrated in the present invention are believed to be new to the art, as will be further described herein with reference to FIGS. 7-8.

As also illustrated in FIG. 2, at least one outside air fan 47 is directly attached to the first door 11. Three outside air fans 47 are depicted. However, more or fewer outside air fans 47 may be employed as the cooling requirement of the end use dictates. Moreover, by having more than one outside air fan 47, the temperature regulating system may continue to function should one of the outside air fans 47 malfunction and cease to operate.

FIG. 3 is the same view of as FIG. 2, but with the top panel 3 removed. As illustrated in FIG. 3, at least one interior air fan 49 is attached to a ceiling panel 51 of the equipment compartment 31. Three interior air fans 49 are depicted. However, more or fewer interior air fans 49 may be employed as the cooling requirement of the end use dictates. Moreover, by having more than one interior air fan 49, the temperature regulating system may continue to function should one of the interior air fans 49 malfunction and cease to operate.

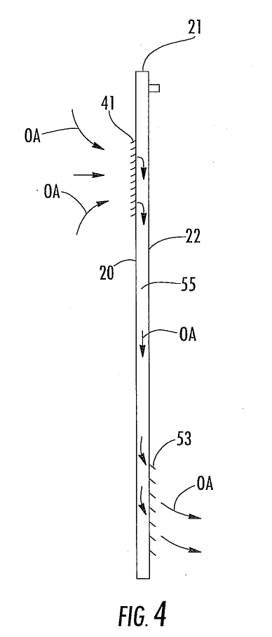

As best illustrated in FIGS. 3 and 4, the second door 21 is preferably of a dual wall construction with an exterior wall 20 facing to an outside environment and an interior wall 22 facing to the second opening 19. A third air vent 53 is formed on the interior wall 22, proximate the bottom of the second door 21, and faces to an opening leading to the battery compartment 33.

As best illustrated in the cross sectional view of FIG. 4, a third air flow passage 55 is formed between the exterior wall 20 and the interior wall 22 of the second door 21. The third air flow passage 55 communicates the first air vent 41 to the third air vent 53. In operation, outside air OA enters the first air vent 41, then travels in a downward direction along the third air flow passage 55, exits via the third air vent 53 and then enters the battery compartment 33. The outside air OA is then drawn through the battery compartment 33 by the outside air fans 47 and into the first door 11.

As best illustrated in FIG. 7, the first door 11 is preferably of a dual wall construction with an exterior wall 57 facing to the outside environment and an interior wall 59 facing to the battery compartment 33. The outside air fans 47 are mounted to the interior wall 59 and are located proximate a bottom of the first door 11 and face to the battery compartment 33. Outside air OA that is drawn into the first door 11 by the outside air fans 47 enters a fourth air flow passage 61. The fourth air flow passage 61 is formed between the exterior wall 57 and the interior wall 59 of the first door 11. The fourth air flow passage 61 communicates the outside air OA passing through the battery compartment 33 upward to the first air flow passage 44 of the heat exchanger 45 via the first air input 48 (See FIG. 5). After passing through the first air flow passages 44 of the heat exchanger 45, the outside air OA exits the cabinet 1 via the first air output 50 (See FIG. 5) to reach the second air vent 43, which is formed in the exterior wall 57 of the first door 11.

As best illustrated in FIG. 8, the interior air IA within the equipment compartment 31 is drawn through the interior air fans 49 and into a ceiling space above the ceiling panel 51. As the ceiling panel 51 is sealed to the first door 11 via the seal 35, the interior air IA then passes into the heat exchanger 45 via the second air input 52 (See FIG. 6). After passing through the second air flow passages 46 of the heat exchanger 45, the interior air IA exits the heat exchanger 45 via the second air output 54 (See FIG. 6) to return to the equipment compartment 31.

By the arrangement illustrated in FIGS. 7 and 8, the heat exchanger 45 will transfer heat between the interior air IA and the outside air OA. If the temperature of the interior air IA is greater than the temperature of the outside air OA, heat will be removed from the equipment compartment 31. Also, by the arrangement illustrated in FIG. 7, the batteries within the battery compartment 33 will be cooled by the outside air OA flowing therethrough. In a preferred embodiment, the outside air fans 47 and/or the interior air fans 49 are variable speed fans, which are controlled by temperature dependent speed controller.

The relative arrangement of components and the dual wall structure of the first and second doors 11 and 21 can be particularly advantageous as a thermal regulating system for the cabinet 1. For example, the dual wall structure of the first and second doors 11 and 21 can greatly reduce radiant heating of the cabinet 1. Radiant heat directed onto the exterior walls 57 and 20 of the first and second doors 11 and 21, respectively, is transferred to the outside air OA flowing within the first and second doors 11 and 21. By this arrangement, the radiant heat is primarily transferred back to the environment via the flow of outside air OA through the doors 11 and 21, rather than acting to further exacerbate the heating of the equipment compartment 31 within the cabinet 1. To this end, the third and fourth sidewalls 26 and 28 may by constructed as dual wall sidewalls with vents proximate top ends of the third and fourth sidewalls 26 and 28 in communication with the outside air OA and vents proximate the bottom ends of the third and fourth sidewalls 26 and 28 in communication with the battery compartment 33, such that outside air OA is drawn through dual wall structures of second, third and fourth sidewalls 17, 26 and 28 to exit via a dual wall structure of the first sidewall 7.

The fourth sidewall 28 is by convention usually referred to as a back wall, as it is opposite to the first door 11 for accessing the equipment compartment 31. One potential advantage of the present invention is that the back wall 28 may not include a vent for exhausting air. Many cabinet designs of the prior art exhaust air from a vent in the back wall 28, which can present problems to customers in that other equipment mounted to the back wall 28 may interfere with the air vent. For example, adaptor plates or adaptor hardware for mounting the cabinet 1 to a pole or wall can interfere with an exhaust vent on the back wall 28.

Further, the dual wall structure of the doors and/or sidewalls may act to reduce noise. The fourth air flow passage 61 between the interior wall 59 and the exterior wall 57 of the first door 11 acts as a sound insulating feature. Moreover, the third air flow passage 55 between the interior wall 22 and the exterior wall 20 of the second door 21 acts as a sound insulating feature. The noise of active components within the cabinet 1, e.g., the interior air fans 49, may not transfer to the outside environment as readily due to the dual wall construction of the doors and/or sidewalls. This may be important in jurisdictions that impose noise restrictions on such equipment and/or to the many customers that demand quite cabinets 1.

Moreover, the placement of the outside air fans 47 near the midpoint of the outside air flow path, between the first air vent 41 and the second air vent 43, may also act to reduce noise. The noise of the outside air fans 47 follows a serpentine path in order to escape via the first or second air vents 41 or 43 to the outside environment. Therefore, the noise level may be greatly reduced compared to a fan mounted directly at a vent to the outside environment.

Further, the dual wall structure of the doors and/or sidewalls may act to reduce the level of contaminants drawn into the cabinet 1. By placing the first and second air vents 41 and 43 proximate the tops of the dual wall structures, ground level contaminants (e.g., pollen, dust, weeds, grass clippings, seeds, crawling insects) may be less likely to be drawn into the cabinet 1 by the action of the outside air fans 47. A typical cabinet is between 48 to 75 inches tall. Therefore, by placing the first and second air vents 41 and 43 in the upper half of a cabinet and/or proximate the top of the cabinet, the air vents 41 and 43 may reside at least 24 inches above the ground level, and more preferably at least 36 inches above the ground level for a 48 inch tall cabinet; and at least 37 inches above the ground level, and more preferably at least 60 inches above the ground level for a 75 inch tall cabinet.

To further reduce noise, sound damping or absorbing materials may be employed within the cabinet 1. For example, a first sheet of sound damping material 63 is attached to the exterior wall 57 of the first door 11 and faces to the fourth air flow passage 61. A second sheet of sound damping material 65 is attached to the heat exchanger 45 and faces to the equipment compartment 31 within the first opening 9. Additional sheets of sound damping material may optionally be attached to the exterior wall 20 of the second door 21 facing to the third air flow passage 55, and/or to the third and fourth side walls 26 and 28 and/or to the top panel 3.

Although the heat exchanger 45 has been illustrated as regulating a temperature of an equipment compartment 31, it should be appreciated that the heat exchanger 45 could be used to regulate a temperature of another area within the cabinet 1 other than the battery compartment 33, through which the outside air OA passes.

In some embodiments, the walls of the doors 57, 59, 20, 22, top panel 3, ceiling panel 51, bottom floor 5, third and fourth sidewalls 26 and 28, as well as other component parts of the cabinet 1 are formed of sheet metal. For example, ⅛ inch thick, aluminum skinned sheet metal that is powder-coat painted may be used to form these components. However, it should be appreciated that other types of materials could be employed for the component parts of the cabinet 1.

Although the present invention has illustrated the first and second air vents 41 and 43 as being located in second and first doors 21 and 11 of the cabinet 1, it should be appreciated that one or both of the first and second air vents 41 and 43 could be located proximate the tops of removable or fixed dual layered sidewalls of the cabinet 1. In other words, a fixed or removable sidewall of the cabinet 1 could be configured with an interior wall and an exterior wall for forming an air flow passage communicating a vent proximate the top of that wall to the battery compartment 33 in the bottom of the cabinet 1.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

We Claim:

1. An outdoor equipment cabinet comprising:
a housing;
a first opening in a first sidewall of said housing;
a first door attached to said housing having a first position providing access to said first opening and a second position closing access to said first opening;
an equipment compartment within said housing and being accessible via said first opening;
a battery compartment located proximate a bottom of said housing and beneath said electronics compartment;
a first air vent located in an upper half of said cabinet relative to a ground level supporting said cabinet;
a heat exchanger directly attached to said first door, said heat exchanger having first and second air flow passages formed therein which are thermally conductive with each other so as to permit a heat exchange therebetween;
a second air vent located in said first door and located in an upper half of said first door as compared to a ground level supporting said cabinet, wherein outside air enters via said first vent and then travels in a downward direction to pass through said battery compartment, and then travels in an upward direction to pass through said first air flow passage of said heat exchanger and then exits via said second vent; and
at least one outside air fan for moving the outside air through said first air flow passage of said heat exchanger.

2. The cabinet according to claim 1, wherein said at least one outside air fan is directly attached to said first door.

3. The cabinet according to claim 1, wherein said at least one outside air fan is a variable speed fan having a temperature dependent speed control.

4. The cabinet according to claim 1, further comprising:
a second opening in a second sidewall of said housing; and
a second door attached to said housing having a first position providing access to said second opening and a second position closing access to said second opening, wherein said first vent is located within said second door.

5. The cabinet according to claim 4, further comprising:
a connection chamber within said housing, which is accessible via said second opening.

6. The cabinet according to claim 4, wherein said second door has a dual wall construction with an exterior wall facing to an outside environment and an interior wall facing to said second opening, and further comprising:
a third air flow passage formed between said exterior wall and said interior wall of said second door, wherein said third air flow passage communicates said first air vent to said battery compartment.

7. The cabinet according to claim 6, wherein said first door has a dual wall construction with an exterior wall facing to the outside environment and an interior wall facing to said first opening, and further comprising:
a fourth air flow passage formed between said exterior wall and said interior wall of said first door, wherein said fourth air flow passage communicates said battery compartment to said first air flow passage of said heat exchanger.

8. The cabinet according to claim 7, wherein said at least one outside air fan is directly attached to said door at an entrance to said fourth air flow passage to pull air from said battery compartment into said fourth air flow passage.

9. The cabinet according to claim 1, wherein said first door has a dual wall construction with an exterior wall facing to an outside environment and an interior wall facing to said first opening, and further comprising:
a third air flow passage formed between said exterior wall and said interior wall of said first door, wherein said third air flow passage communicates said battery compartment to said first air flow passage of said heat exchanger.

10. The cabinet according to claim 9, wherein said at least one outside air fan is directly attached to said door at an entrance to said third air flow passage to pull air from said battery compartment into said third air flow passage.

11. The cabinet according to claim 9, further comprising:
a sound damping material attached to said exterior wall of said first door and facing to said third air flow path.

12. The cabinet according to claim 1, further comprising:
a sound damping material attached to said heat exchanger and facing to said first opening.

13. The cabinet according to claim 1, further comprising:
at least one interior air fan located proximate said equipment compartment for moving the interior air within said equipment compartment through said second air flow passage of said heat exchanger.

14. The cabinet according to claim 13, wherein said heat exchanger includes a plurality of fins, and said first air flow passage includes a plurality of first spaces between said fins of said heat exchanger, and said second air flow passage includes a plurality of second spaces between said fins of said heat exchanger, and wherein said first and second spaces between said fins alternate in a pattern within said heat exchanger.

15. An outdoor equipment cabinet comprising:
a housing;
a first compartment located proximate a bottom of said housing;
an opening in a sidewall of said housing;
a door attached to said housing having a first position providing access to said opening and a second position closing access to said opening, said door having a dual wall construction with an exterior wall facing to an outside environment and an interior wall facing to said opening;
an air vent located in an upper half of said door relative to a ground level supporting said cabinet;
an air flow passage formed between said exterior wall and said interior wall of said door, wherein said air flow passage communicates said air vent to said first compartment; and
at least one outside air fan for moving outside air through said air vent, down said air flow passage and into said first compartment.

16. The cabinet according to claim 15, wherein said opening is a second opening, said sidewall is a second sidewall, said door is a second door, said air vent is a second air vent and said air flow passage is a second air flow passage, and further comprising:
a first opening in a first sidewall of said housing;
a first door attached to said housing having a first position providing access to said first opening and a second position closing access to said first opening, said first door having a dual wall construction with an exterior wall facing to the outside environment and an interior wall facing to said first opening;
a first air vent located in an upper half of said first door relative to the ground level supporting said cabinet; and
a first air flow passage formed between said exterior wall and said interior wall of said first door, wherein said first air flow passage communicates air from said first compartment upward toward said first air vent.

17. The cabinet according to claim 16, further comprising:
a heat exchanger directly attached to said first door, wherein air from said first compartment passes through said heat exchanger prior exiting at said first air vent.

18. The cabinet according to claim 17, wherein said heat exchanger is used to regulate a temperature of air within a second compartment of said cabinet other than said first compartment.

19. An outdoor equipment cabinet comprising:
a housing;
a first air vent located in an upper half of said cabinet relative to a ground level supporting said cabinet;
a second air vent located in an upper half of said cabinet relative to a ground level supporting said cabinet;
a compartment located proximate a bottom of said housing;
a first sidewall of said housing having a dual wall construction with an exterior wall facing to an outside environment and an interior wall facing to an inside of said housing;
a first air flow passage formed between said exterior wall and said interior wall of said first sidewall, wherein said first air flow passage communicates said first air vent to said compartment;
a second sidewall of said housing having a dual wall construction with an exterior wall facing to the outside environment and an interior wall facing to the inside of said housing;
a second air flow passage formed between said exterior wall and said interior wall of said second sidewall, wherein said second air flow passage communicates air from said compartment toward said second air vent; and
at least one outside air fan for moving outside air from said first air vent, down said first air flow passage, into said compartment, up said second air flow passage, and out said second air vent.

20. The cabinet according to claim 19, wherein said first sidewall of said housing is formed by a first door for providing access to a first opening in said housing, and said second sidewall of said housing is formed by a second door for providing access to a second opening in said housing.
